(19) United States
(12) Patent Application Publication
(10) Pub. No.: US 2018/0252754 A1
(43) Pub. Date: Sep. 6, 2018

(54) INSULATION STATE DETECTION DEVICE

(71) Applicant: Yazaki Corporation, Tokyo (JP)

(72) Inventors: Yasuyuki Mochizuki, Shizuoka (JP); Hiroaki Takamatsu, Shizuoka (JP)

(73) Assignee: Yazaki Corporation, Tokyo (JP)

(21) Appl. No.: 15/902,541

(22) Filed: Feb. 22, 2018

(30) Foreign Application Priority Data
Mar. 1, 2017 (JP) 2017-038669

(51) Int. Cl. G01R 27/02; G06G 7/184; H02H 3/16; G01R 31/02; G01R 27/18; G01R 31/00; G01R 31/40

(52) U.S. Cl. CPC G01R 27/025; G06G 7/184; H02H 3/16; G01R 31/40; G01R 27/18; G01R 31/007; G01R 31/025

(57) ABSTRACT

An insulation state detection device includes a positive-side input terminal electrically connected to the positive side of a DC power supply, a negative-side input terminal electrically connected to the negative side, a grounding terminal, a detection circuit which operates based on an operation command to detect an insulation resistance in a measurement section, an input terminal to which an operation command signal is input, an output terminal which outputs a detection result signal related to the detection result of the detection circuit, a circuit board to which these components are mounted, and an insulating accommodation member which encloses at least the entire detection circuit and the entire circuit board and is integrally molded with terminal connecting portions so as to expose the terminal connecting portions outward.

### CROSS-REFERENCE TO RELATED APPLICATION(S)

The present application claims priority to and incorporates by reference the entire contents of Japanese Patent Application No. 2017-038669 filed in Japan on Mar. 1, 2017.

### BACKGROUND OF THE INVENTION

### 1. Field of the Invention

The present invention relates to an insulation state detection device.

### 2. Description of the Related Art

An insulation state detection device which detects an insulation state between a non-grounded high-voltage DC power supply and a predetermined grounding portion has been conventionally known. The conventional insulation state detection device includes a capacitor, a switch that connects the DC power supply and the grounding portion with the capacitor being interposed therebetween, and an arithmetic processor which monitors a charge voltage of the capacitor. The insulation state detection device calculates an insulation resistance between the DC power supply and the grounding portion based on a charge voltage of the capacitor when the DC power supply is connected to the grounding portion for a predetermined time. For example, in a vehicle such as an electric car having a rotary machine as a driving source for traveling, a high-voltage DC power supply for supplying power to the rotary machine is mounted. In this type of vehicle, it is necessary to electrically insulate between the DC power supply and a vehicle body as a grounding portion, and an insulation state detection device is provided in order to detect an insulation state between the DC power supply and the vehicle body (see, for example, Japanese Patent Application Laid-open No. 2016-130706).

Meanwhile, in a conventional insulation state detection device, a capacitor and the like are accommodated in a predetermined place of an inner space of a case together with a circuit board. For example, in the insulation state detection device, a female connector is provided in the inner space of the case, and an opening of the female connector is arranged in an outer wall surface of the case. In this insulation state detection device, at the installation place, a counterpart male connector is inserted into and fitted with the female connector through the opening. Regarding such a conventional insulation state detection device, it is necessary to decide the installation place in consideration of other components, for example, handling of electric wire etc. drawn out from the male connector. Even when a space suitable for the size of the insulation state detection device exists, the insulation state detection device cannot be necessarily installed in the space. Therefore, it is desirable that the insulation state detection device have a high degree of freedom in the installation place.

### SUMMARY OF THE INVENTION

An object of the present invention is to provide an insulation state detection device having a high degree of freedom in an installation place.

In order to achieve the above mentioned above, an insulation state detection device according to one aspect of the present invention includes a positive-side input terminal that includes a terminal connecting portion which is physically and electrically connected to a counterpart positive-side terminal of a counterpart connector and is electrically connected to a positive side of a DC power supply which is not grounded to a grounding portion via the counterpart positive-side terminal, a negative-side input terminal that includes a terminal connecting portion which is physically and electrically connected to a counterpart negative-side terminal of the counterpart connector and is electrically connected to a negative side of the DC power supply via the counterpart negative-side terminal, a grounding terminal that includes a terminal connecting portion which is physically and electrically connected to a counterpart grounding terminal and is electrically connected to the grounding portion via the counterpart grounding terminal, a detection circuit that is electrically connected to the positive-side input terminal, the negative-side input terminal, and the grounding terminal and configured to operate based on an operation command to detect an insulation resistance in a measurement section by the positive-side input terminal, the negative-side input terminal, and the grounding terminal, an input terminal that includes a terminal connecting portion which is physically and electrically connected to a counterpart output terminal of an external arithmetic processing device and in that an operation command signal related to the operation command is input from the arithmetic processing device, an output terminal that includes a terminal connecting portion which is physically and electrically connected to a counterpart input terminal of the arithmetic processing device and outputs a detection result signal related to a detection result of the detection circuit to the arithmetic processing device, a circuit board that has the positive-side input terminal, the negative-side input terminal, the grounding terminal, the detection circuit, the input terminal, and the output terminal mounted on the circuit board, and an insulating accommodation member that encloses at least the entire detection circuit and the entire circuit board and is integrally molded with the positive-side input terminal, the negative-side input terminal, the grounding terminal, the detection circuit, the input terminal, the output terminal and the circuit board so as to expose outward the respective terminal connecting portions of the positive-side input terminal, the negative-side input terminal, the grounding terminal, the input terminal, and the output terminal outward, wherein the accommodation member includes a connector fitting portion to which the counterpart connector is fitted, and in the connector fitting portion, the respective terminal connecting portions of the positive-side input terminal and the negative-side input terminal are arranged to be exposed outward.

According to another aspect of the present invention, in the insulation state detection device, the terminal connecting portions of the grounding terminal, the input terminal, and the output terminal may be formed to be projected in a same direction as and an orthogonal direction to a plane of the circuit board so as to be formed to attach the accommodation member to the arithmetic processing device in the projecting direction and to be respectively connected to the counterpart grounding terminal, the counterpart output terminal, and the counterpart input terminal of the arithmetic processing device.

According to still another aspect of the present invention, in the insulation state detection device, the accommodation member may include a second connector fitting portion to be fitted with a second counterpart connector of the arithmetic processing device, in which the counterpart grounding terminal, the counterpart output terminal, and the counterpart input terminal are arranged, in addition to a first connector fitting portion as the connector fitting portion to be fitted with a first counterpart connector as the counterpart connector, in the second connector fitting portion, the terminal connecting portions of the grounding terminal, the input terminal, and the output terminal may be arranged to be exposed outward.

According to still another aspect of the present invention, the insulation state detection device further may include an arithmetic processor configured to generate the detection result signal related to the detection result based on the detection result of the detection circuit.

According to still another aspect of the present invention, in the insulation state detection device, the detection circuit may include a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and the detection circuit may perform charge/discharge control of the capacitor in the measurement section by controlling the first to fourth switches based on the operation command and output information related to a charge voltage of the capacitor as the detection result.

The above and other objects, features, advantages and technical and industrial significance of this invention will be better understood by reading the following detailed description of the presently preferred embodiment of the invention, when considered in connection with the accompanying drawings.

### BRIEF DESCRIPTION OF THE DRAWINGS

FIG. 1 is a perspective view illustrating an insulation state detection device according to an embodiment;

FIG. 2 is a perspective view of the insulation state detection device according to the embodiment as viewed from another angle;

FIG. 3 is a plan view of the insulation state detection device according to the embodiment as viewed from a side of a connector fitting portion;

FIG. 4 is an exploded perspective view of the insulation state detection device according to the embodiment;

FIG. 5 is an exploded perspective view of the insulation state detection device according to the embodiment as viewed from another angle;

FIG. 6 is a schematic diagram illustrating a circuit configuration of the insulation state detection device according to the embodiment;

FIG. 7 is a perspective view illustrating an insulation state detection device according to a modification;

FIG. 8 is a plan view of the insulation state detection device according to the modification as viewed from a side of a connector fitting portion;

FIG. 9 is an exploded perspective view of the insulation state detection device according to the modification;

FIG. 10 is an exploded perspective view of the insulation state detection device according to the modification as viewed from another angle; and

FIG. 11 is a schematic diagram illustrating a circuit configuration of the insulation state detection device according to the modification.

### DETAILED DESCRIPTION OF THE PREFERRED EMBODIMENTS

An embodiment of an insulation state detection device according to the present invention will be described in detail below with reference to the drawings. It should be noted that the present invention is not limited to the following embodiment.

### Embodiment

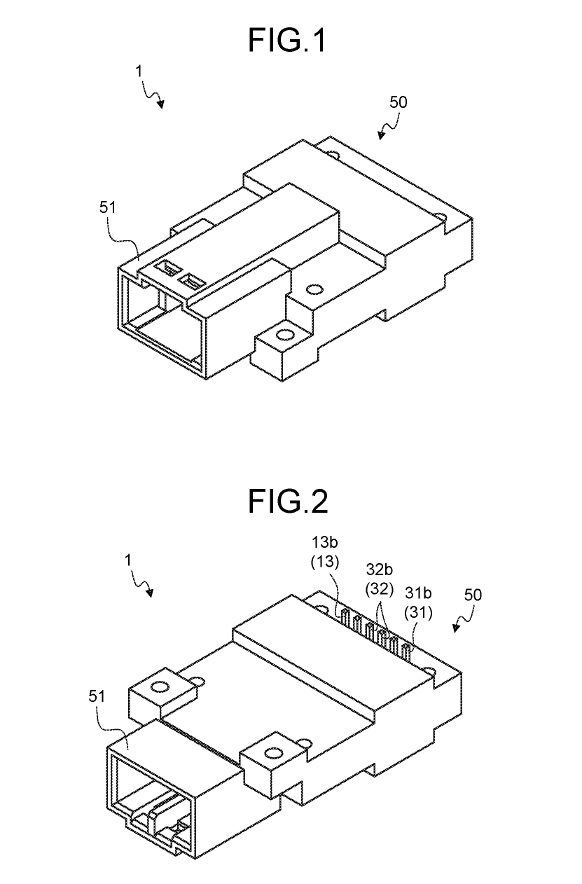

One embodiment of an insulation state detection device according to the present invention will be described with reference to FIGS. 1 to 6. The insulation state detection device detects an insulation state between a DC power supply, which is not grounded to a grounding portion, and the grounding portion.

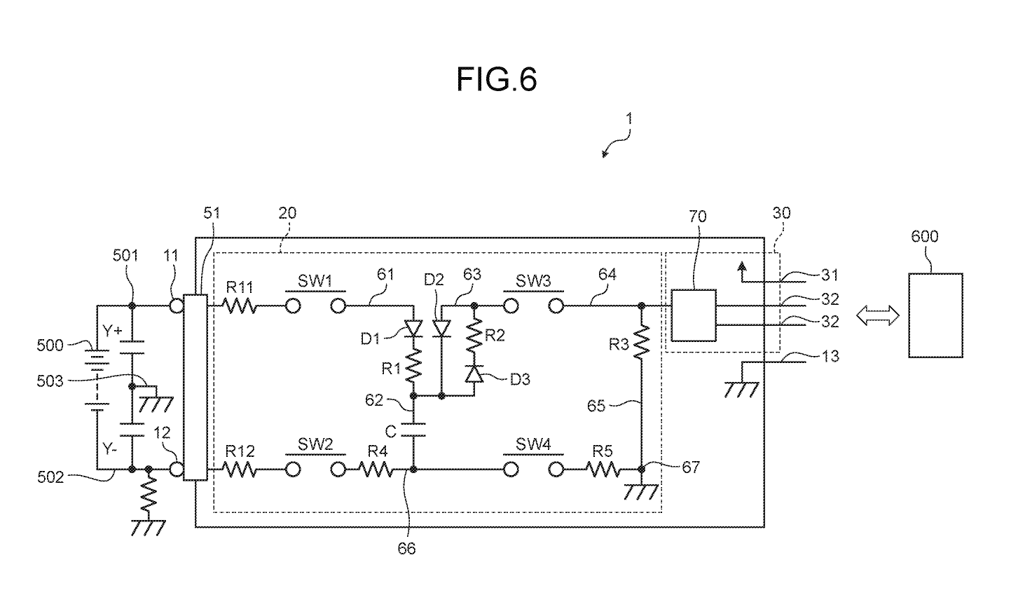

Reference numeral 1 in FIGS. 1 to 6 indicates an insulation state detection device according to the present embodiment. Here, the insulation state detection device 1 is applied to a vehicle (not shown) such as an electric car or a hybrid car having a rotary machine as a driving source for traveling the vehicle, as one example. In this type of vehicle, a low-voltage DC power supply which is not shown (referred to as “DC low-voltage power supply” below) and a high-voltage DC power supply 500 having a higher voltage than the DC low-voltage power supply (referred to as “DC high-voltage power supply” below) (FIG. 6) are mounted. The DC high-voltage power supply 500 supplies power as driving energy to the rotary machine. Therefore, in this vehicle, the DC high-voltage power supply 500 is mounted on a vehicle body as the grounding portion in a non-grounded state, and the DC high-voltage power supply 500 and the vehicle body are electrically insulated. The insulation state detection device 1 is used to determine whether a ground fault occurs in an energization path of the DC high-voltage power supply 500, and detects an insulation state between the DC high-voltage power supply 500 and the vehicle body as a grounding portion. The DC low-voltage power supply and the DC high-voltage power supply 500 are configured as secondary batteries.

The insulation state detection device 1 exchanges signals between the insulation state detection device 1 and an arithmetic processing device provided on the vehicle. Although not shown, an arithmetic processing device (main electronic control unit, referred to as “(main ECU)” below) that executes traveling control such as braking/driving force control is mounted on the vehicle. When a ground fault has occurred, for example, if the vehicle is traveling, the main ECU instructs a driver to stop the vehicle through a display device and an audio device in a vehicle room or performs braking/driving force control to stop the vehicle at a safe place. In addition, when the vehicle is stopping, the main ECU controls the vehicle not to start regardless of an operation by the driver, and informs the driver that the vehicle cannot travel. In this vehicle, the main ECU may be applied as the arithmetic processing device of the vehicle which directly exchanges signals with respect to the insulation state detection device 1. On the other hand, the DC high-voltage power supply 500 in the vehicle includes a battery module which is an assembly of a plurality of battery cells which is not shown, and a battery state (voltage value, temperature, and the like) is monitored by a battery monitor unit of the vehicle. The battery monitor unit includes an arithmetic processing device (referred to as “battery ECU” below) 600 (FIG. 6) to monitor the battery state, and transmits information on the battery state of the DC high-voltage power supply 500 to the main ECU. In this example, the battery ECU 600 is used as an arithmetic processing device of the vehicle which directly exchanges signals with the insulation state detection device 1. In addition, in this example, it is assumed that the insulation state detection device 1 can be attached to the arithmetic processing device of the vehicle (here, battery ECU 600).

A specific example of the insulation state detection device 1 will be described below.

The insulation state detection device 1 operates an operation unit (detection circuit 20 to be described later) to detect an insulation state between the DC high-voltage power supply 500 and the vehicle body as a grounding portion, based on an operation command. In a case where the insulation state detection device 1 does not include an arithmetic processor, a signal related to the operation command (referred to as “operation command signal” below) which is input from an external arithmetic processing device is used. In addition, in a case where the insulation state detection device 1 includes the arithmetic processor, the operation command signal may be a signal output from the arithmetic processor to the operation unit (that is, the arithmetic processor controls the operation unit) or a signal input from an external arithmetic processing device. Here, the insulation state detection device 1 to which the operation command signal is input from the external arithmetic processing device is exemplified, and the battery ECU 600 is used as the arithmetic processing device.

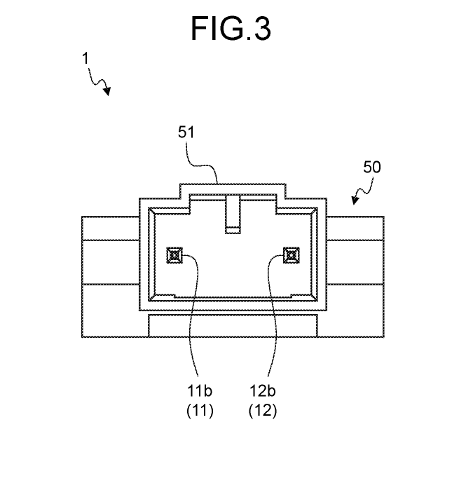

The insulation state detection device 1 includes a positive-side input terminal 11 which is electrically connected to a positive side of the DC high-voltage power supply 500 (that is, a positive side of entire battery module), a negative-side input terminal 12 which is electrically connected to a negative side of the DC high-voltage power supply 500 (that is, a negative side of entire battery module), and a grounding terminal 13 which is electrically connected to the vehicle body as a grounding portion (see FIGS. 3 to 6). In addition, the insulation state detection device 1 includes the detection circuit 20 which is electrically connected to each of the positive-side input terminal 11, the negative-side input terminal 12, and the grounding terminal 13 and operates based on the operation command to detect an insulation resistance in a measurement section caused by the positive-side input terminal 11, the negative-side input terminal 12, and the grounding terminal 13. The measurement section in this example indicates a section between the positive side and the negative side of the DC high-voltage power supply 500 (first measurement section), a section between the positive side of the DC high-voltage power supply 500 and the vehicle body as the grounding portion (second measurement section), and a section between the negative side of the DC high-voltage power supply 500 and the vehicle body as the grounding portion (third measurement section). The insulation state detection device 1 further includes a signal transmission unit 30 which transmits the operation command signal to the detection circuit 20 and outputs a detection result signal related to the detection result of the detection circuit 20. In the insulation state detection device 1, the positive-side input terminal 11, the negative-side input terminal 12, the grounding terminal 13, the detection circuit 20, and the signal transmission unit 30 are mounted on a circuit board 40. The insulation state detection device 1 includes an accommodation member 50 in which the positive-side input terminal 11, the negative-side input terminal 12, the grounding terminal 13, the detection circuit 20, the signal transmission unit 30, and the circuit board 40 are accommodated.

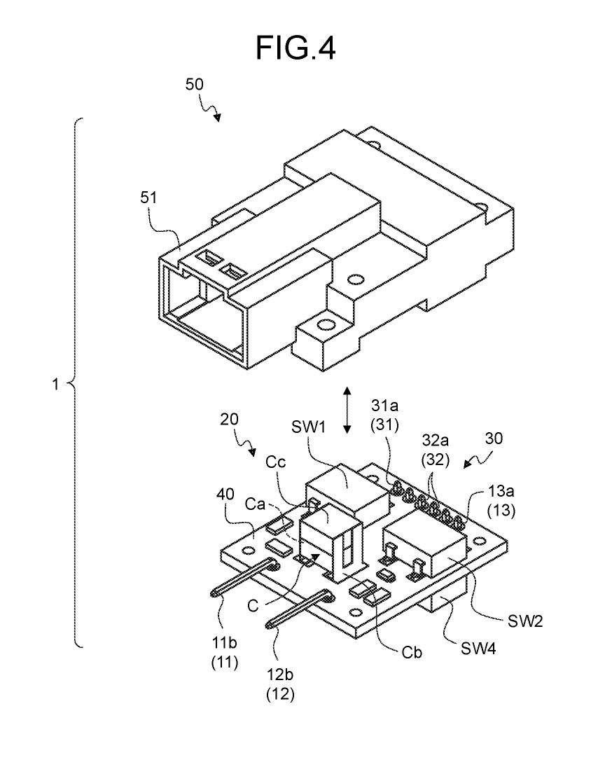

The positive-side input terminal 11 and the negative-side input terminal 12 are formed of a conductive material such as metal. The positive-side input terminal 11 and the negative-side input terminal 12 in this example are formed as male terminals formed by bending a linear conductor as a base material made of a conductive material such as metal into an L shape at a predetermined length or by punching out a metal plate which is a base material in an L shape, and respectively include board connecting portions 11a and 12a and terminal connecting portions 11b and 12b (FIG. 4). In the positive-side input terminal 11 and the negative-side input terminal 12, one of extending portions having an L-shaped bent portion therebetween is each of the board connecting portions 11a and 12a, and the other extending portion is each of the terminal connecting portions 11b and 12b. The board connecting portions 11a and 12a are respectively orthogonal to the terminal connecting portions 11b and 12b.

Each of the board connecting portions 11a and 12a is inserted into a through-hole provided in the circuit board 40 and soldered together with wirings of a circuit pattern of the circuit board 40. The board connecting portions 11a and 12a are attached to the circuit board 40 in this way. The terminal connecting portion 11b of the positive-side input terminal 11 is electrically connected to the positive side of the DC high-voltage power supply 500. The terminal connecting portion 11b is physically and electrically connected to a counterpart positive-side terminal (not shown) electrically connected to the positive side of the DC high-voltage power supply 500, and is electrically connected to the positive side of the DC high-voltage power supply 500 via the counterpart positive-side terminal. The terminal connecting portion 12b of the negative-side input terminal 12 is electrically connected to the negative side of the DC high-voltage power supply 500. The terminal connecting portion 12b is physically and electrically connected to a counterpart negative-side terminal (not shown) electrically connected to the negative side of the DC high-voltage power supply 500, and is electrically connected to the negative side of the DC high-voltage power supply 500 via the counterpart negative-side terminal. Note that, the board connecting portions 11a and 12a may be formed as press-fit terminals. In addition, the board connecting portions 11a and 12a may be formed as surface-mounting-type board connecting portions, and may be mounted on the surface of the circuit board 40 via a terminal plate by reflow soldering and the like.

The positive-side input terminal 11 and the negative-side input terminal 12 are arranged close to one side of the rectangular circuit board 40 and attached to the circuit board 40 with an interval therebetween so that the terminal connecting portions 11b and 12b are arranged on one plane of the circuit board 40. The positive-side input terminal 11 and the negative-side input terminal 12 are attached to the circuit board 40 so that extending directions of the respective board connecting portions 11a and 12a are aligned in a direction orthogonal to the plane of the circuit board 40 and projecting directions of the terminal connecting portions 11b and 12b toward free ends are directed in the same direction (FIG. 4). Therefore, the respective terminal connecting portions 11b and 12b extend in the same direction along the plane of the circuit board 40, and connecting directions of the terminal connecting portions 11b and 12b to the counterpart positive-side terminal and the counterpart negative-side terminal are the same.

In the positive-side input terminal 11 and the negative-side input terminal 12, the entire board connecting portions 11a and 12a are enclosed in the accommodation member 50 together with the circuit board 40, and the accommodation member 50 is integrally molded so as to outwardly expose the terminal connecting portions 11b and 12b. Therefore, in the circuit board 40, since it is possible to shorten an interval (so-called insulation distance) between wirings of circuit pattern at a connecting portion of each of the board connecting portions 11a and 12a, the size can be reduced. Therefore, the insulation state detection device 1 can be made smaller in size.

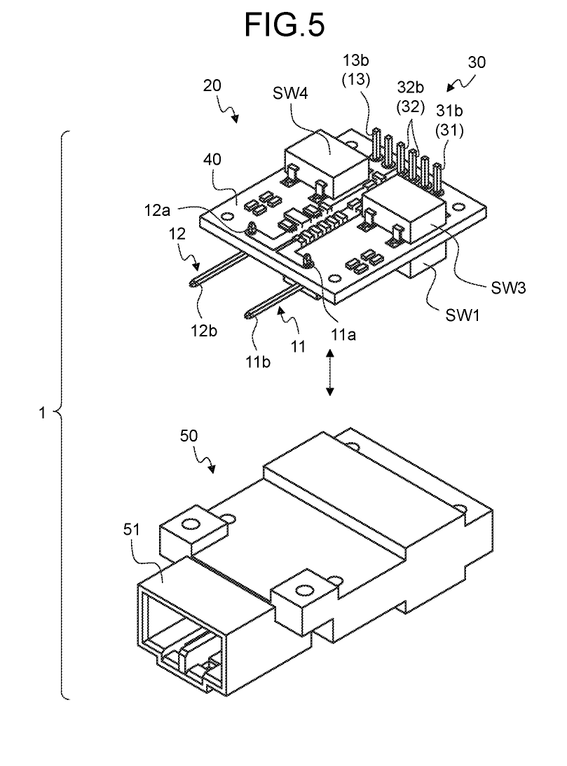

The grounding terminal 13 is a linear conductor formed of a conductive material, such as metal, formed in a straight line, and includes a board connecting portion 13a on one end in the axial direction (FIG. 4) and a terminal connecting portion 13b on the other end (FIGS. 2 and 5).

The board connecting portion 13a is inserted into a through-hole of the circuit board 40 and soldered together with the wiring of the circuit pattern of the circuit board 40. The board connecting portion 13a is attached to the circuit board 40 in this way. The terminal connecting portion 13b is physically and electrically connected to a counterpart grounding terminal (not shown). The terminal connecting portion 13b is electrically connected to the vehicle body as a grounding portion via the counterpart grounding terminal. The exemplified terminal connecting portion 13b is connected to the counterpart grounding terminal included in the battery ECU 600. Note that, the board connecting portion 13a may be formed as a press-fit terminal. In addition, the board connecting portion 13a may be formed as a surface-mounting-type board connecting portion, and may be mounted on the surface of the circuit board 40 via the terminal plate by the reflow soldering and the like.

The grounding terminal 13 is arranged close to one side of the rectangular circuit board 40 and attached to the circuit board 40. Here, the grounding terminal 13 is arranged close to the side opposite to the side where the positive-side input terminal 11 and the negative-side input terminal 12 are arranged. In addition, the grounding terminal 13 is attached to the circuit board 40 so that the terminal connecting portion 13b is arranged on the other plane of the circuit board 40 (place opposite to the plane where terminal connecting portion 11b of positive-side input terminal 11 and terminal connecting portion 12b of negative-side input terminal 12 are arranged). The grounding terminal 13 is attached to the circuit board 40 in a state where the axial direction of the grounding terminal 13 is aligned in a direction orthogonal to the plane of the circuit board 40 and is vertically provided. Therefore, relative to the plane of the circuit board 40, the grounding terminal 13 is projected to the side opposite to the side where the terminal connecting portion 11b of the positive-side input terminal 11 and the terminal connecting portion 12b of the negative-side input terminal 12 are arranged.

In the grounding terminal 13, the accommodation member 50 is integrally molded so that the entire board connecting portion 13a is enclosed in the accommodation member 50 together with the circuit board 40 and the terminal connecting portion 13b is exposed outward.

The detection circuit 20 includes an electronic component which operates based on the operation command and the wiring of the circuit pattern provided on the circuit board 40 and is mounted on the circuit board 40. The exemplary detection circuit 20 is a so-called flying capacitor method which is well-known in this technical field, and includes a capacitor which is charged with a voltage according to the insulation resistance of the measurement section (first to third measurement sections) and a plurality of switches to perform charge/discharge control of the capacitor. In the insulation state detection device 1 according to the present embodiment, an operation command signal related to the charge/discharge control of the capacitor is input from the battery ECU 600. The battery ECU 600 controls charge and discharge of the capacitor for each of the first to third measurement sections by appropriately performing on-control to the switch (contact closing control) or off-control to the switch (contact opening control). Then, the battery ECU 600 measures a charge voltage of the capacitor for each of the first to third measurement sections and calculates the insulation resistances in the second measurement section (between positive side of DC high-voltage power supply 500 and vehicle body as grounding portion) and the third measurement section (between negative side of DC high-voltage power supply 500 and vehicle body as grounding portion). The battery ECU 600 determines the insulation state of the DC high-voltage power supply 500 based on the values of the insulation resistances.

The detection circuit 20 according to the present embodiment includes a single capacitor C (FIGS. 4 and 6) and first to fourth switches SW1 to SW4 (FIGS. 5 and 6).

The capacitor C includes a positive-side terminal Ca and a negative-side terminal Cb (FIG. 4). Each of the positive-side terminal Ca and the negative-side terminal Cb is a part of a metal terminal projected outward from a capacitor body Cc and is soldered together with the wiring of the circuit pattern of the circuit board 40. As will be described later, on a circumference of the capacitor C is filled with a high-temperature synthetic resin material when the accommodation member 50 is integrally molded. Therefore, a capacitor having a high heat resistance (for example, ceramic capacitor) which can withstand the heat generated at the time of the integral molding is used for the capacitor C.

The first switch SW1 electrically connects or disconnects between the positive-side input terminal 11 and the positive-side terminal Ca of the capacitor C. The second switch SW2 electrically connects or disconnects between the negative-side input terminal 12 and the negative-side terminal Cb of the capacitor C. The third switch SW3 electrically connects or disconnects between a grounding point 67 (FIG. 6), which will be described later, having the same potential as the vehicle body as a grounding portion and the positive-side terminal Ca. The fourth switch SW4 electrically connects or disconnects between the grounding point 67 and the negative-side terminal Cb. The first to fourth switches SW1 to SW4 respectively include switching elements. In this example, an optical MOS-FET is used as the switching element, and this contributes to miniaturize the first to fourth switches SW1 to SW4. Therefore, the insulation state detection device 1 can be made smaller in size. Here, as the first to fourth switches SW1 to SW4, other high-voltage resistant relays, insulation switches, and the like can be used instead of the optical MOS-FETs.

The first to fourth switches SW1 to SW4 are controlled based on the operation command so that the detection circuit 20 performs the charge/discharge control of the capacitor C in the measurement section (first to third measurement sections). Then, the detection circuit 20 outputs information related to the charge voltage of the capacitor C to the signal transmission unit 30 as the detection result.

The signal transmission unit 30 according to the present embodiment is configured to transmit signals between the detection circuit 20 and the battery ECU 600. In the signal transmission unit 30, an operation command signal is input from the battery ECU 600, and the operation command signal is output to the detection circuit 20. In addition, the information related to the charge voltage of the capacitor C in the first to third measurement sections is input from the detection circuit 20 to the signal transmission unit 30 as the detection result, and the detection result signal related to the detection result is output to the battery ECU 600.

The signal transmission unit 30 includes at least an input terminal 31 to which the operation command signal is input from the battery ECU 600 and an output terminal 32 which outputs the detection result signal to the battery ECU 600 (FIGS. 2 and 4 to 6).

The input terminal 31 is a linear conductor formed of a conductive material, such as metal, formed in a straight line, and includes a board connecting portion 31a on one end in the axial direction (FIG. 4) and a terminal connecting portion 31b on the other end (FIGS. 2 and 5). The input terminal 31 is formed in the same shape as the grounding terminal 13.

The board connecting portion 31a is inserted into a through-hole of the circuit board 40 and soldered together with the wiring of the circuit pattern of the circuit board 40. The board connecting portion 31a is attached to the circuit board 40 in this way. The terminal connecting portion 31b is physically and electrically connected to a counterpart output terminal (not shown). The terminal connecting portion 31b is connected to the counterpart output terminal included in the battery ECU 600. Note that, the board connecting portion 31a may be formed as a press-fit terminal. In addition, the board connecting portions 31a may be formed as a surface-mounting-type board connecting portion, and may be mounted on the surface of the circuit board 40 via the terminal plate by the reflow soldering and the like.

The input terminal 31 is arranged close to one side of the rectangular circuit board 40 and attached to the circuit board 40. Here, the input terminal 31 is arranged close to the same side where the grounding terminal 13 is arranged. The input terminal 31 is arranged along the side and arranged apart from the grounding terminal 13. In addition, the input terminal 31 is arranged so that the projecting direction of the terminal connecting portion 31b of the input terminal 31 relative to the plane of the circuit board 40 is the same as the projecting direction of the terminal connecting portion 13b of the grounding terminal 13. Therefore, the terminal connecting portions 31b and 13b of the input terminal 31 and the grounding terminal 13 in this example are projected in the direction orthogonal to the plane of the circuit board 40 and toward the same direction.

Regarding the input terminal 31, the accommodation member 50 is integrally molded so that the entire board connecting portion 31a is enclosed in the accommodation member 50 together with the circuit board 40 and the terminal connecting portion 31b is exposed outward.

The output terminal 32 is a linear conductor formed of a conductive material, such as metal, formed in a straight line, and includes a board connecting portion 32a on one end in the axial direction (FIG. 4) and a terminal connecting portion 32b on the other end (FIGS. 2 and 5). The output terminal 32 is formed in the same shape as the grounding terminal 13 and the input terminal 31.

The board connecting portion 32a is inserted into a through-hole of the circuit board 40 and soldered together with the wiring of the circuit pattern of the circuit board 40. The board connecting portion 32a is attached to the circuit board 40 in this way. The terminal connecting portion 32b is physically and electrically connected to a counterpart input terminal (not shown). The terminal connecting portion 32b is connected to the counterpart input terminal included in the battery ECU 600. Note that, the board connecting portion 32a may be formed as a press-fit terminal. In addition, the board connecting portion 32a may be formed as a surface-mounting-type board connecting portion, and may be mounted on the surface of the circuit board 40 via the terminal plate by the reflow soldering and the like.

The output terminal 32 is arranged close to one side of the rectangular circuit board 40 and attached to the circuit board 40. Here, the output terminal 32 is arranged close to the same side where the grounding terminal 13 and the input terminal 31 are arranged. The output terminal 32 is arranged along the side and arranged apart from the grounding terminal 13 and the input terminal 31. In addition, the output terminal 32 is arranged so that the projecting direction of the terminal connecting portion 32b of the output terminal 32 relative to the plane of the circuit board 40 is the same as the projecting direction of the terminal connecting portion 13b of the grounding terminal 13. Therefore, the terminal connecting portions 32b, 13b, and 31b of the output terminal 32, the grounding terminal 13, and the input terminal 31 in this example are projected in the direction orthogonal to the plane of the circuit board 40 and toward the same direction.

Regarding the output terminal 32, the accommodation member 50 is integrally molded so that the entire board connecting portion 32a is enclosed in the accommodation member 50 together with the circuit board 40 and the terminal connecting portion 32b is exposed outward.

Here, as described above, the insulation state detection device 1 is attached to the arithmetic processing device of the vehicle (here, battery ECU 600). In this case, to improve mounting workability of the insulation state detection device 1, it is desirable that the attaching direction to the battery ECU 600 and the projecting directions of the terminal connecting portions 13b, 31b, and 32b of the grounding terminal 13, the input terminal 31, and the output terminal 32 be aligned in the same direction. The terminal connecting portions 13b, 31b, and 32b are projected from the accommodation member 50 in the projecting direction described above, and are formed to attach the accommodation member 50 which forms the main appearance shape of the insulation state detection device 1 to the battery ECU 600 and to be respectively connected to the counterpart grounding terminal, the counterpart output terminal, and the counterpart input terminal of the battery ECU 600. Therefore, regarding the insulation state detection device 1, since an attaching work to the battery ECU 600 and a work for connecting the respective terminal connecting portions 13b, 31b, and 32b to the counterpart grounding terminal, the counterpart output terminal, and the counterpart input terminal can be performed as one operation, the mounting workability becomes excellent.

Furthermore, as described above, regarding the grounding terminal 13, the input terminal 31, and the output terminal 32, the entire board connecting portions 13a, 31a, and 32a are enclosed in the accommodation member 50 together with the circuit board 40. Therefore, in the circuit board 40, since it is possible to shorten an interval (insulation distance) between wirings of circuit pattern at a connecting portion of each of the board connecting portions 13a, 31a, and 32a, the size can be reduced. Therefore, the insulation state detection device 1 can be made smaller in size in this regard.

The circuit board 40 is formed in a rectangular shape as described above. Electronic components are mounted on both sides of the exemplified circuit board 40, and the wirings of the circuit pattern are provided on each plane. The wirings will be described later.

The accommodation member 50 is formed of an insulating material such as a synthetic resin. The accommodation member 50 encloses at least the entire detection circuit 20 and the entire circuit board 40 and is integrally molded with the positive-side input terminal 11, the negative-side input terminal 12, the grounding terminal 13, the detection circuit 20, the signal transmission unit 30, and the circuit board 40 so as to expose the terminal connecting portions 11b, 12b, and 13b of the positive-side input terminal 11, the negative-side input terminal 12, and the grounding terminal 13 outward. In a mold used to integrally mold the accommodation member 50, the circuit board 40 is arranged on which the positive-side input terminal 11, the negative-side input terminal 12, the grounding terminal 13, the detection circuit 20, and the signal transmission unit 30 are mounted. The accommodation member 50 is molded with a synthetic resin material filled in the mold. The exemplified accommodation member 50 is formed so that the terminal connecting portion 31b of the input terminal 31 and the terminal connecting portion 32b of the output terminal 32 are exposed outward.

In this way, the accommodation member 50 is integrally molded so as to enclose at least the entire detection circuit 20 and the entire circuit board 40 and covers the entire detection circuit 20 and the entire circuit board 40 in a closely contacted state. Accordingly, contact of gas and liquid with and entrance of foreign substances in the detection circuit 20 and the circuit board 40 can be prevented. Therefore, in the insulation state detection device 1, a protection function of the detection circuit 20, the circuit board 40, and the like can be enhanced, and durability can be improved. In addition, the accommodation member 50 is integrally molded together with the circuit board 40 so as to enclose the board connecting portions 11a and 12a of the L-shaped positive-side input terminal 11 and negative-side input terminal 12. Therefore, the accommodation member 50 receives forces applied to the board connecting portions 11a and 12a when counterpart connectors are inserted and removed, and a load applied to a connection portions between the board connecting portions 11a and 12a and the circuit board 40 can be reduced. Furthermore, in addition to the board connecting portions 11a and 12a, the accommodation member 50 is integrally molded with the circuit board 40 so as to enclose the board connecting portion 13a of the grounding terminal 13, the board connecting portion 31a of the input terminal 31, and the board connecting portion 32a of the output terminal 32. Therefore, even if an external input is applied to the accommodation member 50, a load applied to connection portions between the board connecting portions 11a, 12a, 13a, 31a, and 32a and the circuit board 40 can be reduced. The external input is, for example, a force transmitted from the vehicle body such as a road surface input and a force input by vibration at the time of travel of the vehicle. When the insulation state detection device 1 is attached to a battery of the vehicle using the rotary machine as a power source such as an electric car, a force input from an attachment point due to thermal expansion or thermal contraction of the battery is included in the external input to the accommodation member 50. According to the load reduction effect describe above, the insulation state detection device 1 can maintain physical and electrical connecting states among the board connecting portions 11a, 12a, 13a, 31a, and 32a and the circuit board 40 at the time of an assembly action or at the time when the insulation state detection device 1 is used. Therefore, the durability can be also improved from this point.

In addition, since the accommodation member 50 is integrally molded with the circuit board 40 and the like, it is not necessary to provide a gap with the circuit board and the like in a case as a conventional accommodation member, and it is not necessary to provide a color and a fastening member which have been traditionally necessary for attaching the circuit board and the like in the case, the size can be reduced. Therefore, the insulation state detection device 1 can be formed in a smaller size. Furthermore, in the circuit board 40, since it is possible to shorten each interval (insulation distance) between the wirings of the circuit pattern by the accommodation member 50 which is integrally molded, the circuit pattern can be reduced in size, and the size of the circuit board 40 can be reduced. Therefore, by integrally molding the accommodation member 50 according to the size of the circuit board 40 and the like, the size of the insulation state detection device 1 can be reduced from this point.

Specifically, the accommodation member 50 includes a connector fitting portion 51 in which a counterpart connector (not shown) of the DC high-voltage power supply 500 is fitted (FIGS. 1 to 3). The counterpart connector includes the counterpart positive-side terminal and the counterpart negative-side terminal described above. By fitting the counterpart connector into the connector fitting portion 51, the counterpart positive-side terminal is fitted into the terminal connecting portion 11b of the positive-side input terminal 11, and the counterpart negative-side terminal is fitted into the terminal connecting portion 12b of the negative-side input terminal 12. Therefore, in the connector fitting portion 51, the terminal connecting portion lib of the positive-side input terminal 11 and the terminal connecting portion 12b of the negative-side input terminal 12 are arranged to be exposed outward. Here, the terminal connecting portion 11b of the positive-side input terminal 11 and the terminal connecting portion 12b of the negative-side input terminal 12 are formed as male terminals, and the counterpart positive-side terminal and the counterpart negative-side terminal are formed as female terminals. The counterpart connector is inserted into the connector fitting portion 51. Therefore, the terminal connecting portion 11b of the positive-side input terminal 11 and the terminal connecting portion 12b of the negative-side input terminal 12 are arranged in the connector fitting portion 51 in a state of extending along the insertion and removal direction between the connector fitting portion 51 and the counterpart connector (FIG. 3).

In this way, in the insulation state detection device 1, the connector fitting portion 51 is provided in the accommodation member 50. In comparison with the traditional one which prepares components (circuit board 40 and the like) accommodated in the accommodation member 50 separately from the accommodation member 50 and assemblies them with each other to integrate them, the size in the orthogonal direction relative to the plane of the circuit board 40 can be reduced. Therefore, as long as the size of the insulation state detection device 1 in the orthogonal direction can be made equal to that of the traditional one, the electronic components can be mounted on both sides of the circuit board 40 as described above, the size of the insulation state detection device 1 in the direction along the plane of the circuit board 40 can be reduced.

In the accommodation member 50, the terminal connecting portion 13b of the grounding terminal 13, the terminal connecting portion 31b of the input terminal 31, and the terminal connecting portion 32b of the output terminal 32 are projected from an outer wall surface without having a connector structure (FIG. 2). Furthermore, the insulation state detection device 1 includes terminals having the same shape as the grounding terminal 13 other than the grounding terminal 13, in consideration of the mounting work described above, terminal connecting portions of the terminals are arranged with intervals and arranged in the same direction as the terminal connecting portions 13b, 31b, and 32b. For example, power of the DC low-voltage power supply to operate the detection circuit 20 can be supplied from the battery ECU 600. In this case, a power supply terminal having the same shape as the grounding terminal 13 and the like is provided in the insulation state detection device 1, and it is preferable that a terminal connecting portion of the power supply terminal be physically and electrically connected to a counterpart power supply terminal of the battery ECU 600. The accommodation member 50 encloses a board connecting portion of the terminal, and a terminal connecting portion of the terminal is projected from the outer wall surface. Therefore, in the circuit board 40, since it is possible to shorten an interval (insulation distance) between wirings of a circuit pattern at a connecting portion of the board connecting portion of the terminal, the size can be reduced. Therefore, the insulation state detection device 1 can be made smaller in size in this regard.

The circuit configuration of the insulation state detection device 1 configured in this way will be briefly described with reference to FIG. 6.

In the DC high-voltage power supply 500, a positive-side power supply line 501 and a negative-side power supply line 502 are electrically insulated from a ground line 503. The positive-side power supply line 501 corresponds to an energization path of a positive-side output of the DC high-voltage power supply 500. The negative-side power supply line 502 corresponds to an energization path of a negative-side output of the DC high-voltage power supply 500. The ground line 503 corresponds to the grounding portion of the vehicle body and the like. The insulation state detection device 1 detects an insulation resistance between the positive-side power supply line 501 and the ground line 503 as a positive-side insulation state and detects an insulation resistance between the negative-side power supply line 502 and the ground line 503 as a negative-side insulation state.

In the DC high-voltage power supply 500, Y capacitors Y+ and Y− to reduce common mode noise are provided. The Y capacitor Y+ connects between the positive-side power supply line 501 and the ground line 503. The Y capacitor Y− connects between the negative-side power supply line 502 and the ground line 503.

In the insulation state detection device 1, the positive-side input terminal 11 is connected to the positive-side power supply line 501 via the counterpart positive-side terminal, and the negative-side input terminal 12 is connected to the negative-side power supply line 502 via the counterpart negative-side terminal.

The positive-side input terminal 11 is connected to one end of the first switch SW1 via a resistor R11. A wiring 61 of the circuit pattern is connected to the other end of the first switch SW1. A wiring 62 of the circuit pattern is connected to the wiring 61 via a series circuit including a diode D1 and a resistor R1. The diode D1 permits energization from the wiring 61 to the wiring 62.

The positive-side terminal Ca of the capacitor C is connected to the wiring 62. The wiring 62 is further connected to the wiring 63 of the circuit pattern via a diode D2 and connected to the wiring 63 via a series circuit including a diode D3 and a resistor R2. The diode D2 permits energization from the wiring 63 to the wiring 62. The diode D3 permits energization from the wiring 62 to the wiring 63.

The wiring 63 is connected to one end of the third switch SW3. A wiring 64 of the circuit pattern is connected to the other end of the third switch SW3. The wiring 64 is connected to a wiring 65 of the circuit pattern via a resistor R3.

On the other hand, the negative-side input terminal 12 is connected to one end of the second switch SW2 via a resistor R12. The other end of the second switch SW2 is connected to a wiring 66 of the circuit pattern via a resistor R4. To the wiring 66, the negative-side terminal Cb of the capacitor C and one end of the fourth switch SW4 are connected. The other end of the fourth switch SW4 is connected to the wiring 65 via a resistor R5.

The grounding point 67 is connected to the wiring 65. In this example, the grounding terminal 13 is connected to the wiring 65. The grounding point 67 is connected to the ground line 503 via the grounding terminal 13.

An input circuit 70 is connected to the wiring 64. In the input circuit 70, a signal in the wiring 64 is converted into a signal suitable for calculation processing in the battery ECU 600. The output terminal 32 is connected to the input circuit 70.

In the insulation state detection device 1, the intervals (insulation distance) between the wirings 61 to 66 are shortened.

The insulation state detection device 1 performs on-control (contact closing control) to the first switch SW1 and the second switch SW2 and performs off-control (contact opening control) to the third switch SW3 and the fourth switch SW4 based on the operation command signal from the battery ECU 600. The insulation state detection device 1 energizes the first measurement section (between positive side and negative side of DC high-voltage power supply 500) and charges the capacitor C for a predetermined time (very short time). The battery ECU 600 performs off-control (contact opening control) to the first switch SW1 and the second switch SW2 and performs on-control (contact closing control) to the third switch SW3 and the fourth switch SW4. The battery ECU 600 discharges the capacitor C and measures a charge voltage V0 of the capacitor C. The charge voltage V0 indicates a value corresponding to the insulation resistance between the positive side and the negative side of the DC high-voltage power supply 500.

In addition, the insulation state detection device 1 performs on-control (contact closing control) to the first switch SW1 and the fourth switch SW4 and performs off-control (contact opening control) to the second switch SW2 and the third switch SW3 based on the operation command signal from the battery ECU 600. The insulation state detection device 1 energizes the second measurement section (between positive side of DC high-voltage power supply 500 and vehicle body (grounding point 67) as grounding portion) and charges the capacitor C for a predetermined time (very short time). The battery ECU 600 performs off-control (contact opening control) to the first switch SW1 and the second switch SW2 and performs on-control (contact closing control) to the third switch SW3 and the fourth switch SW4. The battery ECU 600 discharges the capacitor C and measures a charge voltage VCn of the capacitor C. The charge voltage VCn indicates a value corresponding to the insulation resistance between the positive side of the DC high-voltage power supply 500 and the vehicle body as the grounding portion.

In addition, the insulation state detection device 1 performs on-control (contact closing control) to the second switch SW2 and the third switch SW3 and performs off-control (contact opening control) to the first switch SW1 and the fourth switch SW4 based on the operation command signal from the battery ECU 600. The insulation state detection device 1 energizes the third measurement section (between negative side of DC high-voltage power supply 500 and vehicle body (grounding point 67) as grounding portion) and charges the capacitor C for a predetermined time (very short time). The battery ECU 600 performs off-control (contact opening control) to the first switch SW1 and the second switch SW2 and performs on-control (contact closing control) to the third switch SW3 and the fourth switch SW4. The battery ECU 600 discharges the capacitor C and measures a charge voltage VCp of the capacitor C. The charge voltage VCp indicates a value corresponding to the insulation resistance between the negative side of the DC high-voltage power supply 500 and the vehicle body as the grounding portion.

Based on the charge voltages V0, VCn, and VCp or insulation resistances R0, RCn, and RCp respectively calculated based on the charge voltages V0, VCn, and VCp, the battery ECU 600 determines the insulation state of the DC high-voltage power supply 500.

As described above, since the insulation state detection device 1 can be miniaturized by integrally molding the accommodation member 50 with the circuit board 40 and the like, a degree of freedom in selecting an installation place is increased. In addition, according to the reduction in size, the weight of the insulation state detection device 1 can be reduced. In addition, since the accommodation member 50 includes the connector fitting portion 51 and is formed as a connector, the insulation state detection device 1 can be attached to the vehicle body, an electric junction box, or an arithmetic processing device of the vehicle. The degree of freedom of the insulation state detection device 1 in the installation place is increased from this point, and in addition, components can be standardized. For example, by attaching the insulation state detection device 1 to the arithmetic processing device of the vehicle, the arithmetic processing device can have a function for detecting an insulation state. At that time, the insulation state detection device 1 can be attached to the arithmetic processing device by connector-fitting the insulation state detection device 1 into the counterpart connector of the arithmetic processing device, and the number of attaching points to the arithmetic processing device can be reduced. Therefore, traditional colors and fastening members, which have been used to attach the insulation state detection device 1 to the arithmetic processing device, can be made unnecessary or reduced. Therefore, the insulation state detection device 1 has a high degree of freedom in the installation place in this point. In addition, in the insulation state detection device 1, since a power supply system to operate the detection circuit 20 and a power supply system of the arithmetic processing device of the vehicle can be used in common, the degree of freedom in the installation place can be increased in accordance with the reduction in size from this point, and cost can be reduced. Furthermore, in the insulation state detection device 1, since the integrally molded accommodation member 50 makes a traditional moisture-proof agent which has covered the detection circuit and the circuit board unnecessary, the size and the weight of the insulation state detection device 1 can be reduced from this point, and the degree of freedom in the installation place can be increased.

Here, in the insulation state detection device 1 according to the present embodiment, the positive-side input terminal 11 and the negative-side input terminal 12 molded in L shape are exemplified. However, the shapes of the positive-side input terminal 11 and the negative-side input terminal 12 are not necessarily limited to such a shape. For example, the positive-side input terminal 11 and the negative-side input terminal 12 may be linearly molded and attached to be orthogonal to the plane of the circuit board 40.

In the insulation state detection device 1 according to the present embodiment, a part of the accommodation member 50 is formed as the connector fitting portion 51, and the connector fitting portion 51 is exposed outward. However, the connector fitting portion 51 may be formed as follows with respect to a main body of the accommodation member 50. For example, an insertion-opening-side part (insertion opening of counterpart connector) of the connector fitting portion 51 is projected outward from an outer wall surface of the main body of the accommodation member 50, and the remaining portion may be buried in the main body of the accommodation member 50. Even in this case, the inner space of the connector fitting portion 51 is communicated with the outside of the accommodation member 50, and the terminal connecting portions 11b and 12b arranged in the inner space are exposed outward. In addition, the entire connector fitting portion 51 may be buried in the main body of the accommodation member 50. Even in this case, the inner space of the connector fitting portion 51 is communicated with the outside of the accommodation member 50, and the terminal connecting portions 11b and 12b arranged in the inner space are exposed outward. For example, by providing an opening in the outer wall surface of the main body and forming the connector fitting portion 51 on the inner side of the opening, the accommodation member 50 in this case uses the opening as the insertion opening for the counterpart connector.

Modification

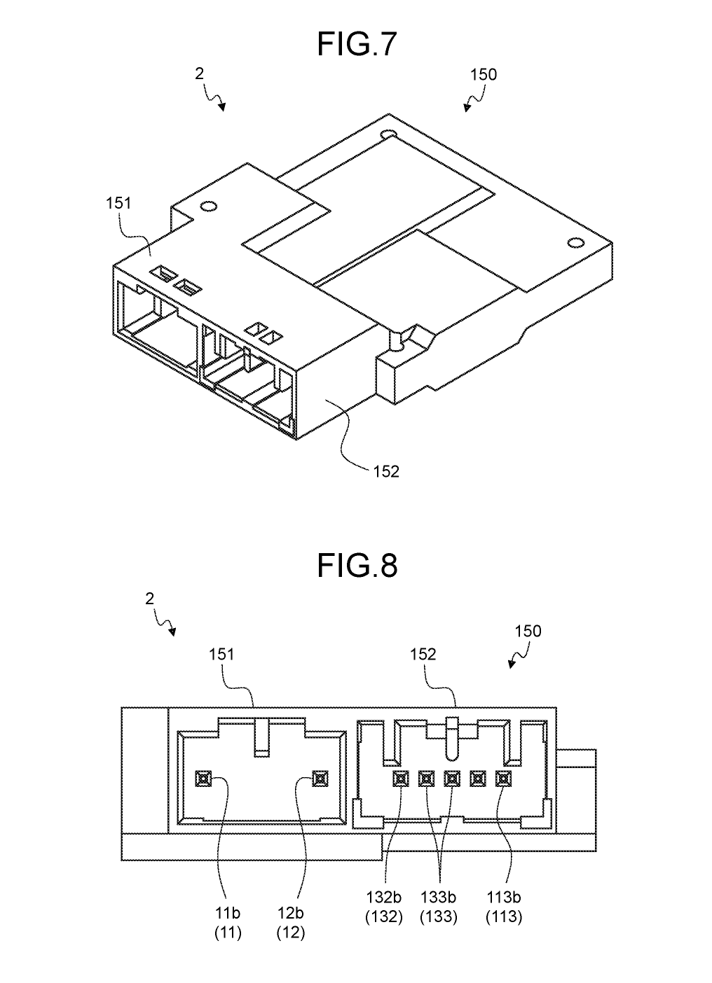

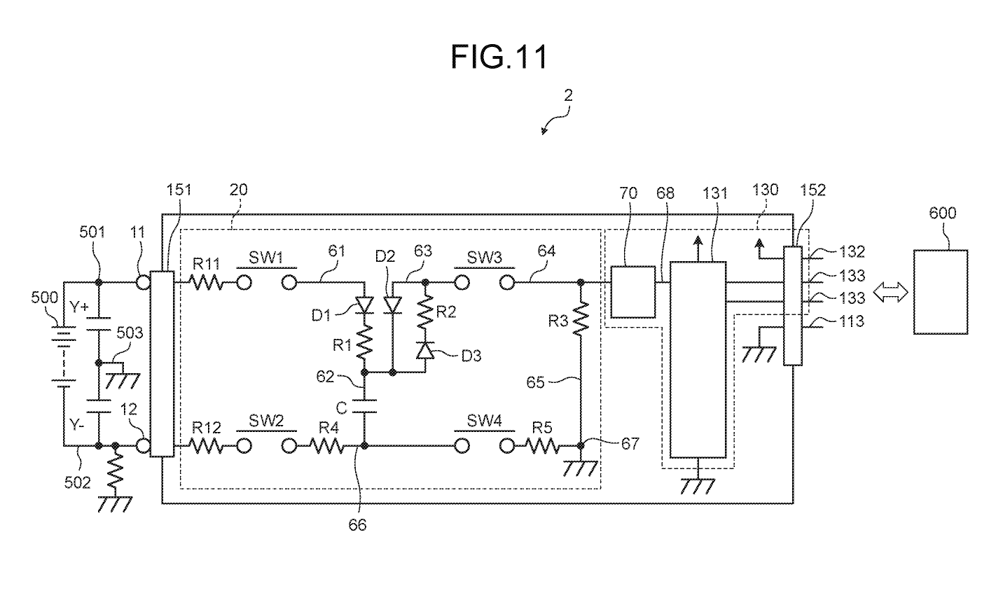

A reference numeral 2 in FIGS. 7 to 11 indicates an insulation state detection device according to the present modification. In the insulation state detection device 2, the signal transmission unit 30 of the insulation state detection device according to the above embodiment is changed to a signal transmission unit 130 to be described later (FIG. 11) and the accommodation member 50 is changed to an accommodation member 150 to be described later (FIGS. 7 to 10).

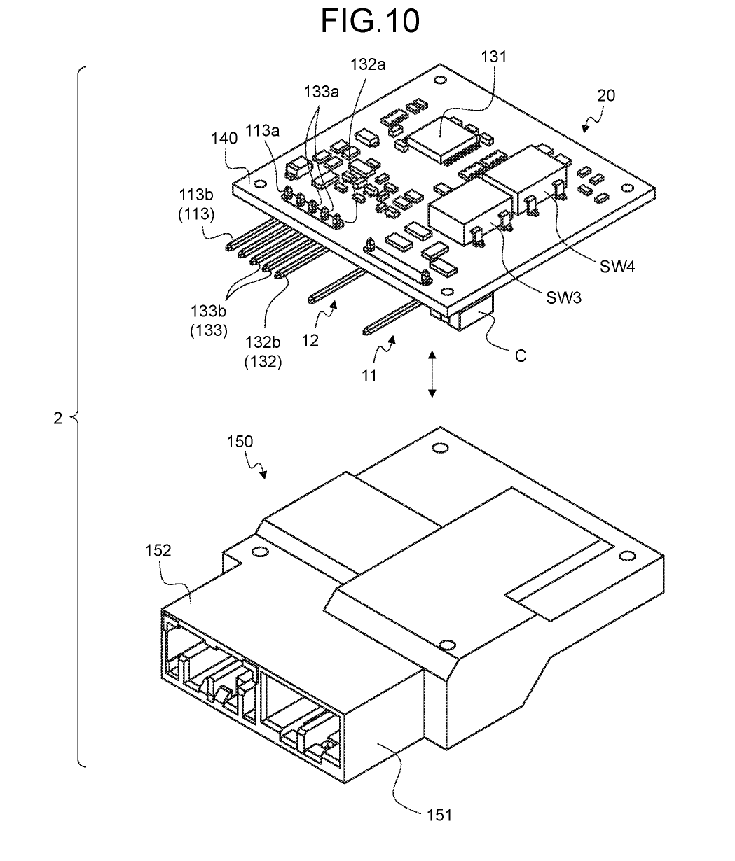

The signal transmission unit 130 according to the present modification includes at least an arithmetic processor 131 (FIG. 10) which generates a detection result signal related to the detection result, based on the detection result of the detection circuit 20, and an input terminal 132 and an output terminal 133 (FIGS. 8 to 10) similar to the input terminal 31 and the output terminal 32 of the signal transmission unit 30 according to the embodiment.

The arithmetic processor 131 operates based on power from a DC low-voltage power supply and an operation command signal from a battery ECU 600. The arithmetic processor 131 has a part of the arithmetic processing function of the battery ECU 600 according to the embodiment, and performs charge/discharge control of a capacitor C, measures charge voltages VO, Vcn, and VCp of the capacitor C, and calculates insulation resistances RO, Rcn, and RCp based on the respective charge voltages V0, Vcn, and VCp based on the operation command signal from the battery ECU 600 input via the input terminal 132. The arithmetic processor 131 transmits calculation values of the insulation resistances R0, Rcn, and RCp to the battery ECU 600 via the output terminal 133. The battery ECU 600 determines an insulation state of the DC high-voltage power supply 500 based on the insulation resistances R0, Rcn, and RCp.

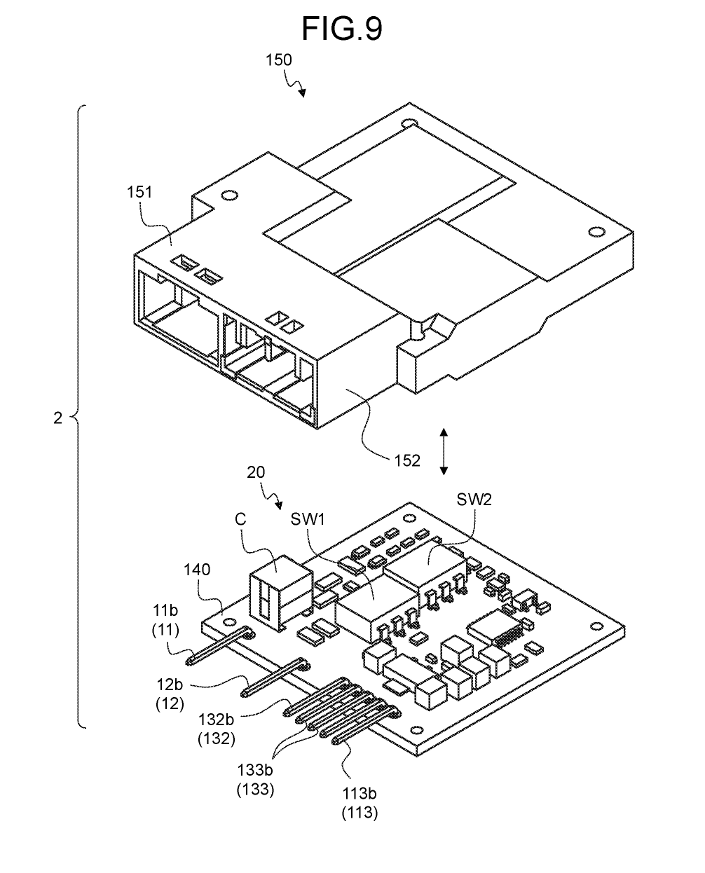

The input terminal 132 has a board connecting portion 132a (FIG. 10) and a terminal connecting portion 132b (FIG. 9) similarly to the input terminal 31 according to the embodiment. Furthermore, the output terminal 133 has a board connecting portion 133a (FIG. 10) and a terminal connecting portion 133b (FIG. 9) similarly to the output terminal 32 according to the embodiment. However, the input terminal 132 and the output terminal 133 according to the present modification are formed in an L shape of which each extending parts are orthogonal to each other, similarly to the positive-side input terminal 11 and the negative-side input terminal 12. Therefore, the input terminal 132 and the output terminal 133 each has two extending portions as having the L-shaped bent portion as a boundary. One of the extending portions of the input terminal 132 is the board connecting portion 132a, and the other extending portion is the terminal connecting portion 132b. One of the extending portions of the output terminal 133 is the board connecting portion 133a, and the other extending portion is the terminal connecting portion 133b.

Furthermore, in the present modification, a grounding terminal 113 is formed in an L shape corresponding to the input terminal 132 and the output terminal 133 (FIGS. 9 and 10). The grounding terminal 113 has two extending portions as having the L-shaped bent portion as a boundary, and one of the extending portions is a board connecting portion 113a, and the other extending portion is a terminal connecting portion 113b.

Similarly to the accommodation member 50 according to the embodiment, an accommodation member 150 according to the present modification includes a connector fitting portion (referred to as “first connector fitting portion” below) 151 to be fitted with the counterpart connector described above (referred to as “first counterpart connector” below) (FIGS. 7 to 10). The first connector fitting portion 151 is similar to the connector fitting portion 51 in the accommodation member 50 according to the embodiment and includes a terminal connecting portion 11b of the positive-side input terminal 11 and a terminal connecting portion 12b of the negative-side input terminal 12 which are exposed outward. In the present modification, the terminal connecting portion 11b of the positive-side input terminal 11 and the terminal connecting portion 12b of the negative-side input terminal 12 are arranged in the first connector fitting portion 151 in a state of extending in the insertion and removal direction between the first connector fitting portion 151 and the first counterpart connector.

In addition to the first connector fitting portion 151, the accommodation member 150 includes a second connector fitting portion 152 (FIGS. 7 to 10). The second connector fitting portion 152 is a portion to be fitted with a second counterpart connector. The second counterpart connector has at least a counterpart grounding terminal, a counterpart output terminal, and a counterpart input terminal. By fitting the second counterpart connector with the second connector fitting portion 152, the counterpart grounding terminal, the counterpart output terminal, and the counterpart input terminal are respectively fitted with the grounding terminal 113, the input terminal 132, and the output terminal 133. Therefore, in the second connector fitting portion 152, the grounding terminal 113, the input terminal 132, and the output terminal 133 are arranged in a state where the respective terminal connecting portions 113b, 132b, and 133b are exposed outward. Here, each of the terminal connecting portions 113b, 132b, and 133b is formed as a male terminal, and each of the counterpart grounding terminal, the counterpart output terminal, and the counterpart input terminal is formed as a female terminal.

The second counterpart connector is inserted into the second connector fitting portion 152. Therefore, each of the terminal connecting portions 113b, 132b, and 133b is arranged in the second connector fitting portion 152 in a state of extending along the insertion and removal direction between the second connector fitting portion 152 and the second counterpart connector.

Here, in the insulation state detection device 2, on a circuit board 140, the grounding terminal 113, the input terminal 132, and the output terminal 133 are arranged on the same side where the positive-side input terminal 11 and the negative-side input terminal 12 are arranged (FIGS. 9 and 10). On the circuit board 140, the respective terminal connecting portions 11b, 12b, 113b, 132b, and 133b of the positive-side input terminal 11, the negative-side input terminal 12, the grounding terminal 113, the input terminal 132, and the output terminal 133 are arranged on the same plane, and the positive-side input terminal 11, the negative-side input terminal 12, the grounding terminal 113, the input terminal 132, and the output terminal 133 are attached so that the respective terminal connecting portions 11b, 12b, 113b, 132b, and 133b are projected toward the same direction. Therefore, in the accommodation member 150, the first connector fitting portion 151 and the second connector fitting portion 152 are aligned in the plane of the circuit board 140, and the insertion and removal directions with respect to the respective counterpart connectors are set to be the same.

The circuit configuration of the insulation state detection device 2 configured in this way will be briefly described with reference to FIG. 11.

The circuit configuration of the insulation state detection device 2 corresponds to a configuration in which the following components are added to the circuit configuration of the insulation state detection device 1 according to the embodiment.

In the present modification, the wiring 64 is connected to a wiring 68 of a circuit pattern via an input circuit 70. The arithmetic processor 131 is connected to the wiring 68. In the input circuit 70, a signal in the wiring 64 is converted into a signal suitable for calculation processing in the arithmetic processor 131. The output terminal 133 is connected to the arithmetic processor 131.

Even if the insulation state detection device 2 according to the present modification is configured as described above, an effect similar to that of the insulation state detection device 1 according to the embodiment can be obtained. For example, with the insulation state detection device 2, intervals (insulation distances) of the wirings of the circuit pattern from the input circuit 70, to the grounding terminal 113, the input terminal 132, and the output terminal 133 can be shortened. Therefore, since the insulation state detection device 2 can be miniaturized by integrally molding the accommodation member 150 with the circuit board 140 and the like, a degree of freedom in selecting an installation place is increased. In addition, according to the reduction in size, the weight of the insulation state detection device 2 can be reduced. In addition, since the accommodation member 150 includes a first connector fitting portion 151 and a second connector fitting portion 152 and is formed as a connector, the insulation state detection device 2 can be attached to the vehicle body, an electric junction box, or an arithmetic processing device of the vehicle. The degree of freedom of the insulation state detection device 2 in the installation place is increased from this point, and in addition, components can be standardized. Furthermore, in the insulation state detection device 2, since the integrally molded accommodation member 150 makes a traditional moisture-proof agent which has covered the detection circuit and the circuit board unnecessary, the size and the weight of the insulation state detection device 2 can be reduced from this point, and the degree of freedom in the installation place can be increased.

Here, in the insulation state detection device 2 according to the present modification, each of the positive-side input terminal 11, the negative-side input terminal 12, the grounding terminal 113, the input terminal 132, and the output terminal 133 is formed in an L shape. However, as described in the embodiment, it is preferable that the positive-side input terminal 11, the negative-side input terminal 12, the grounding terminal 113, the input terminal 132, and the output terminal 133 be linearly formed and be attached to be orthogonal to the plane of the circuit board 140.

In the insulation state detection device 2 according to the present modification, a part of the accommodation member 150 is formed as the first connector fitting portion 151 and the second connector fitting portion 152, and the first connector fitting portion 151 and the second connector fitting portion 152 are exposed outward. However, the first and the second connector fitting portions 151 and 152 may be formed with respect to the main body portion of the accommodation member 150 as described in the embodiment. That is, an insertion-opening-side part (insertion opening of counterpart connector) of each of the first and the second connector fitting portions 151 and 152 is projected outward from an outer wall surface of the main body of the accommodation member 150, and the remaining portion may be buried in the main body of the accommodation member 150. In addition, the entire first connector fitting portion 151 and second connector fitting portion 152 may be buried in the main body of the accommodation member 150.

In an insulation state detection device according to the present embodiment, an accommodation member is integrally molded so as to enclose at least an entire detection circuit and an entire circuit board and covers the entire detection circuit and the entire circuit board in a closely contacted state. Accordingly, contact of gas and liquid with and entrance of foreign substances in the detection circuit and the circuit board can be prevented. Therefore, in the circuit board, for example, intervals (insulation distance) between wirings of the circuit pattern can be reduced. Accordingly, the circuit pattern can be reduced in size, and the size of the circuit board can be reduced. Therefore, by integrally molding the accommodation member in accordance with the size of the circuit board and the like, the size of the insulation state detection device can be reduced, and a degree of freedom in the installation place can be increased.

Although the invention has been described with respect to the specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An insulation state detection device comprising:
a positive-side input terminal that includes a terminal connecting portion which is physically and electrically connected to a counterpart positive-side terminal of a counterpart connector and is electrically connected to a positive side of a DC power supply which is not grounded to a grounding portion via the counterpart positive-side terminal;
a negative-side input terminal that includes a terminal connecting portion which is physically and electrically connected to a counterpart negative-side terminal of the counterpart connector and is electrically connected to a negative side of the DC power supply via the counterpart negative-side terminal;
a grounding terminal that includes a terminal connecting portion which is physically and electrically connected to a counterpart grounding terminal and is electrically connected to the grounding portion via the counterpart grounding terminal;
a detection circuit that is electrically connected to the positive-side input terminal, the negative-side input terminal, and the grounding terminal and configured to operate based on an operation command to detect an insulation resistance in a measurement section by the positive-side input terminal, the negative-side input terminal, and the grounding terminal;
an input terminal that includes a terminal connecting portion which is physically and electrically connected to a counterpart output terminal of an external arithmetic processing device and in that an operation command signal related to the operation command is input from the arithmetic processing device;
an output terminal that includes a terminal connecting portion which is physically and electrically connected to a counterpart input terminal of the arithmetic processing device and outputs a detection result signal related to a detection result of the detection circuit to the arithmetic processing device;
a circuit board that has the positive-side input terminal, the negative-side input terminal, the grounding terminal, the detection circuit, the input terminal, and the output terminal mounted on the circuit board; and
an insulating accommodation member that encloses at least the entire detection circuit and the entire circuit board and is integrally molded with the positive-side input terminal, the negative-side input terminal, the grounding terminal, the detection circuit, the input terminal, the output terminal and the circuit board so as to expose outward the respective terminal connecting portions of the positive-side input terminal, the negative-side input terminal, the grounding terminal, the input terminal, and the output terminal, wherein
the accommodation member includes a connector fitting portion to which the counterpart connector is fitted, and
in the connector fitting portion, the respective terminal connecting portions of the positive-side input terminal and the negative-side input terminal are arranged to be exposed outward.

2. The insulation state detection device according to claim 1, wherein
the terminal connecting portions of the grounding terminal, the input terminal, and the output terminal are formed to be projected in a same direction as and an orthogonal direction to a plane of the circuit board so as to be formed to attach the accommodation member to the arithmetic processing device in the projecting direction and to be respectively connected to the counterpart grounding terminal, the counterpart output terminal, and the counterpart input terminal of the arithmetic processing device.

3. The insulation state detection device according to claim 1, wherein
the accommodation member includes a second connector fitting portion to be fitted with a second counterpart connector of the arithmetic processing device, in which the counterpart grounding terminal, the counterpart output terminal, and the counterpart input terminal are arranged, in addition to a first connector fitting portion as the connector fitting portion to be fitted with a first counterpart connector as the counterpart connector,
in the second connector fitting portion, the terminal connecting portions of the grounding terminal, the input terminal, and the output terminal are arranged to be exposed outward.

4. The insulation state detection device according to claim 1, further comprising:
an arithmetic processor configured to generate the detection result signal related to the detection result based on the detection result of the detection circuit.

5. The insulation state detection device according to claim 2, further comprising:
an arithmetic processor configured to generate the detection result signal related to the detection result based on the detection result of the detection circuit.

6. The insulation state detection device according to claim 3, further comprising:
an arithmetic processor configured to generate the detection result signal related to the detection result based on the detection result of the detection circuit.

7. The insulation state detection device according to claim 1, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.

8. The insulation state detection device according to claim 2, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.

9. The insulation state detection device according to claim 3, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.

10. The insulation state detection device according to claim 4, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.

11. The insulation state detection device according to claim 5, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.

12. The insulation state detection device according to claim 6, wherein
the detection circuit includes a capacitor which is charged with a voltage according to the insulation resistance in the measurement section, a first switch which electrically connects or disconnects between the positive-side input terminal and a positive-side terminal of the capacitor, a second switch which electrically connects or disconnects between the negative-side input terminal and a negative-side terminal of the capacitor, a third switch which electrically connects or disconnects between a grounding point having the same potential as the grounding portion and the positive-side terminal, and a fourth switch which electrically connects or disconnects between the grounding point and the negative-side terminal, and
the detection circuit performs charge/discharge control of the capacitor in the measurement section by controlling the first to fourth switches based on the operation command and outputs information related to a charge voltage of the capacitor as the detection result.
